(19) United States
(12) Patent Application Publication
(10) Pub. No.: US 2010/0000859 A1
(43) Pub. Date: Jan. 7, 2010

(54) SPUTTERING APPARATUS AND MANUFACTURING APPARATUS FOR LIQUID CRYSTAL DEVICE

(75) Inventor: Shinichi FUKADA, Hachioji (JP)

Correspondence Address: HARNESS, DICKEY & PIERCE, P.L.C., P.O. BOX 828, BLOOMFIELD HILLS, MI, 48303, US

(73) Assignee: SEIKO EPSON CORPORATION, Tokyo (JP)

(21) Appl. No.: 12/495,056

(22) Filed: Jun. 30, 2009

(30) Foreign Application Priority Data
Jul. 3, 2008 (JP) 2008-174824

(51) Int. Cl. C23C 14/34

(52) U.S. Cl. 204/298.02

(57) ABSTRACT

A sputtering apparatus includes: a film forming chamber housing a substrate, and a sputtered particle ejecting section ejecting a sputtered particle from a pair of targets facing each other with a plasma generation region between the targets. In the device, the sputtered particle ejecting section includes an electron capture unit that is disposed opposite to the film forming chamber and captures an electron in the plasma generation region, and a sputtered particle attach section that is disposed adjacent to the film forming chamber and attaches the particle.

The entire disclosure of Japanese Patent Application No. 2008-174824, filed Jul. 3, 2008 is expressly incorporated by reference herein.

### BACKGROUND

1. Technical Field

The present invention relates to a sputtering apparatus and a manufacturing apparatus for a liquid crystal device.

2. Related Art

A liquid crystal device used as light modulation means for projection type displays such as a liquid crystal projector includes a pair of substrates, a sealant provided between the substrates at their marginal areas, and a liquid crystal layer sealed between the substrates. The inner surfaces of the pair of the substrates have electrodes that apply a voltage to the liquid crystal layer. At the inner sides of the electrodes, orientation films are formed that control the orientation of liquid crystal molecules when a non-selective voltage is applied. The liquid crystal device structured as above modulates light from a light source based on the orientation change of the liquid crystal molecules when a non-selective voltage is applied and when a selective voltage is applied, so as to form a display image.

As for the orientation film, one is generally used that is a film of polymer such as polyimide having a side-chain alkyl group and the surface of which film has been subjected to rubbing. While such rubbing is convenient, various problems arise because the method gives orientation property to the polyimide film by physically rubbing it. Specifically, the following problems are pointed out. (1) It is difficult to maintain uniform orientation. (2) Traces caused by rubbing likely remain. (3) It is not possible to control an orientation direction as well as selectively control a pretilt angle. (4) The method is not suitable for being applied to a liquid crystal panel using a multi domain method for achieving a wide view angle. (5) The method causes static electricity generated from a glass substrate to destroy thin film transistor elements or to damage orientation films, resulting in the yield being lowered. (6) Display failures likely occur that are caused by foreign materials generated from a rubbing cloth.

In addition, when such orientation film made from an organic material is used for an apparatus equipped with a high-output light source such as a liquid crystal projector, the organic material is damaged by light energy, causing orientation failures. Particularly, for downsized and high-brightness projectors, the damages are accelerated. In the projectors, energy per unit area incident on the liquid crystal panel increases. Polyimide decomposes itself due to the absorption of incident light, and heat generated by the light absorption further accelerates the decomposition. As a result, the orientation film is heavily damaged, lowering display characteristics of the apparatus.

In order to solve such problems, a sputtering apparatus (hereinafter may be referred to as a sputter apparatus) as a film formation device has been proposed in which sputtering is conducted so that sputtered particles ejected from targets oppositely disposed are obliquely incident on a substrate from one direction, and an inorganic orientation film is formed on the substrate, which film has a plurality of columnar structure of crystals grown in a direction oblique to the substrate. For example, refer to JP-A-2007-286401. In addition, since an electron trapping unit (an electron capture unit) is provided, electrons in the plasma generation region are captured so as to stably generate plasma. The electron trapping unit is, for example, made of a conductive member.

However, the sputtering method above has problems to be solved due to the following reasons. The orientation film is usually made of an insulating material. Thus, sputtered particles emitted from the sputter apparatus have an insulating property or turn to have an insulating property in the film forming process. A part of the emitted sputtered particles attaches to a surface of the conductive member included in the electron trapping unit, and covers the surface thereof. If the surface of the conductive member is insulated in accordance with the deposition of the sputtered particles, the electrons are not well captured, causing the sputter rate to be reduced. In order to form a film with good quality, frequent maintenance of the electron trapping unit is required. As a result, the substantial film forming efficiency is decreased.

### SUMMARY

An advantage of the invention is to provide a sputtering apparatus and a manufacturing apparatus for a liquid crystal device that can efficiently form a film by sputtering.

According to a first aspect of the invention, a sputtering apparatus includes: a film forming chamber housing a substrate; and a sputtered particle ejecting section ejecting a sputtered particle from a pair of targets facing each other with a plasma generation region between the targets. In the device, the sputtered particle ejecting section includes an electron capture unit that is disposed opposite to the film forming chamber and captures an electron in the plasma generation region, and a sputtered particle attach section that is disposed adjacent to the film forming chamber and attaches the particle.

According to the sputtering apparatus of the invention, since the sputtered particles flying from the plasma generation region are selectively attached to the sputtered particle attach section, the sputtered particles are prevented from attaching to the electron capture unit. When the sputtered particles are attached to the sputtered particle attach section, electrons sufficiently smaller than the sputtered particles go though the sputtered particle attach section, and are well captured by the electron capture unit. If the sputtered particles have an insulating property, the function of capturing electrons and the sputter rate decrease when the sputtered particles are deposited on the surface of the electron capture unit. However, according to the invention, the sputtered particle attach section prevents the failures described above. As a result, the maintenance cycle of the electron capture unit is extended, whereby labor and time required for the maintenance can be suppressed. Accordingly, the substantial operating time of the device is extended compared to the conventional device, thereby a film can be efficiently formed by sputtering.

In the sputtering apparatus, the sputtered particle attach section may be included in a part of the electron capture unit. With this structure, a part of the sputtered particle attach section where the sputtered particles are not attached can be used as the electron capture unit.

In the sputtering apparatus, the sputtered particle attach section may include a plurality of plate members. In the device, the plate members are disposed so that each face direction of the plate members coincides with an ejecting direction of the sputtered particle and each face of the plate members is parallel to each other. With this structure, the sputtered particles flying from the plasma generation region can be well attached to the plurality of the plate members. The plurality of the plate members included in the sputtered particle attach section is disposed such that each face direction of the plate members is parallel to the ejecting direction of the sputtered particles. Therefore, the sputtered particles are captured by the plate members while electrons in the plasma generation region can reach well the electron capture unit through a space between the plate members.

In the sputtering apparatus, a length of the plate member in a direction toward the plasma generation region may be larger than a mean free path of the sputtered particle. With this structure, since the length of the plate member along the plasma generation region is larger than the mean free path of the sputtered particles, the sputtered particles flying from the plasma generation region to the electron capture unit can be easily collided against a surface of the plate member. As a result, the sputtered particles hardly attach to the electron capture unit of the plate members.

In the sputtering apparatus, a space between the plurality of the plate members may be smaller than a mean free path of the sputtered particle. With this structure, since the space between the plate members is shorter than the mean free path of the sputtered particles, the sputtered particles flying from the plasma generation region can be easily collided against the surface of the plate member when the particles pass through the space between the plurality of the plate members. As a result, the sputtered particles hardly attach to the electron capture unit of the plate members.

In the sputtering apparatus according, the sputtered particle ejecting section may include a sputter gas supply unit that supplies a sputter gas to the plasma generation region, and is disposed opposite to the plasma generation region of the electron capture unit. With this method, the sputtered particles are blown up by the sputter gas injected from the gas supply unit, and attached to a position apart from the electron capture unit of the sputtered particle attach section.

According to a second aspect of the invention, a manufacturing apparatus of a liquid crystal device includes: a liquid crystal layer sandwiched between a pair of substrates facing each other; an inorganic orientation film formed at an inner side of at least one of the substrates; and the sputtering apparatus of the first aspect. In the device, the inorganic orientation film is formed by the sputtering apparatus.

According to the manufacturing apparatus for a liquid crystal device of the invention, an inorganic orientation film superior in orientation property with a desired columnar structure can be efficiently manufactured.

### BRIEF DESCRIPTION OF THE DRAWINGS

The invention will be described with reference to the accompanying drawings, wherein like numbers reference like elements.

FIG. 1 is a view schematically showing a rough structure of a sputtering apparatus of an embodiment.

FIG. 2 is a side view schematically showing a sputtered particle ejecting section when it is viewed from a plus (+) Xa direction.

FIG. 3 is a front view schematically showing the sputtered particle ejecting section when it is viewed from the plus (+) Xa direction.

FIG. 4 is a view explaining a structure of plate members.

FIG. 5 is a view explaining a state in which sputtered particles are attached to an electron capture unit.

### DESCRIPTION OF EXEMPLARY EMBODIMENTS

Embodiments of the invention are described below with reference to accompanying drawings. The technical scope of the invention is not limited to the following embodiments. Note that scales of members in the drawings referred to hereinafter are adequately changed so that they can be recognized. In the following drawings, a carrying direction of a substrate in a film forming chamber is defined as an X direction. A thickness direction of the substrate is defined as a Z direction. A direction orthogonal to each of the X and Z directions is defined as a Y direction. A thickness direction of a target is defined as a Za direction. An ejecting direction of sputtered particles is defined as an Xa direction.

Sputtering Apparatus and Manufacturing Apparatus for Liquid Crystal Device

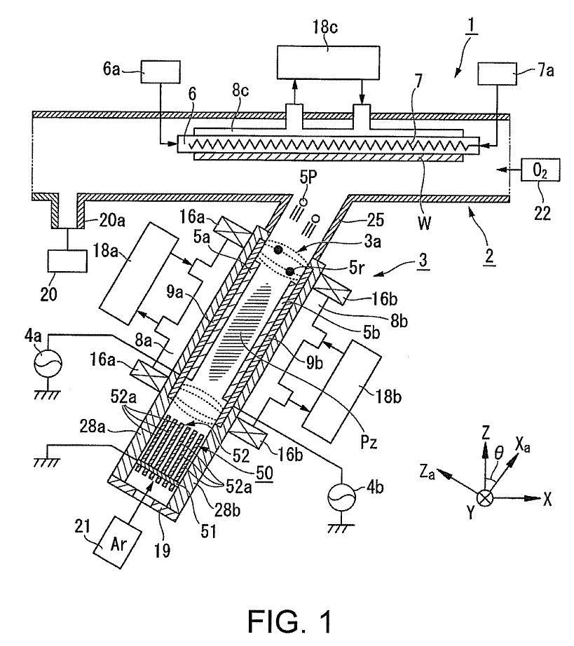

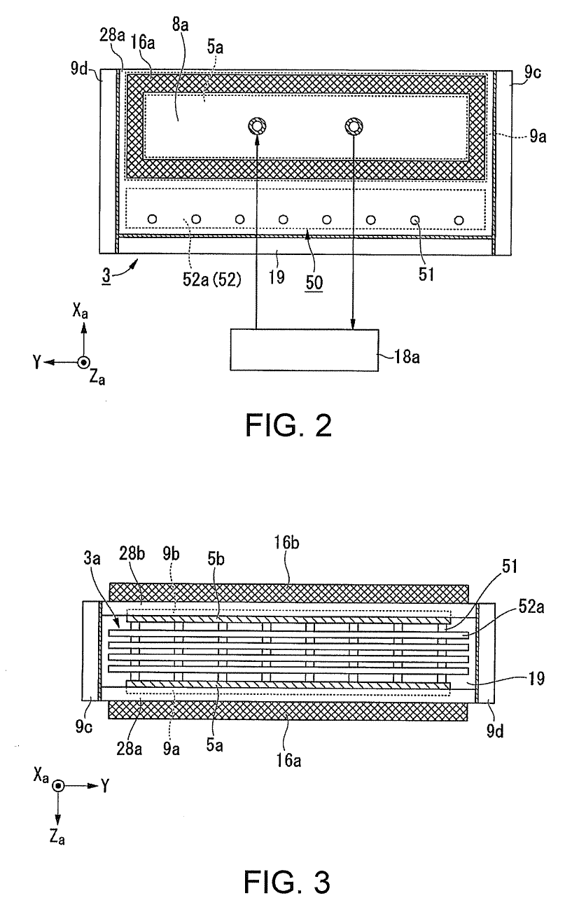

FIG. 1 is a diagram showing a sputtering apparatus (hereinafter referred to as a sputter apparatus) according to an embodiment of the invention. FIG. 2 is a side view showing a sputtered particle ejecting section included in a part of the sputter apparatus when it is viewed from a plus (+) Xa direction. FIG. 3 is a front view showing the sputtered particle ejecting section when it is viewed from the plus (+) Xa direction.

As shown in FIG. 1, a sputter apparatus 1 is one of manufacturing apparatus for a liquid crystal device of the invention, and forms an inorganic orientation film by sputtering on a substrate W serving as a member of the liquid crystal device. The sputter apparatus 1 includes a film forming chamber 2 that is a vacuum camber and houses the substrate W, and a sputtered particle ejecting section 3 that ejects sputtered particles to a surface of the substrate W to form an orientation film made from an inorganic material. The sputtered particle ejecting section 3 includes a first gas supply unit (a sputter gas supply unit) 21 that supplies argon gas for electric discharge to its plasma generation region.

The film forming chamber 2 includes a second gas supply unit 22 that supplies oxygen gas as reaction gas reacting with an orientation film material flying over the substrate W housed inside the chamber to form the inorganic orientation film. The film forming chamber 2 is also coupled through a pipe 20a to an exhaust control device 20 that controls the internal pressure of the chamber 2 for achieving a desired vacuum level.

A connection section 25 connecting with the sputtered particle ejecting section 3 is formed in a manner such that projecting outward from a wall surface of a lower side of the figure of the film forming chamber 2. The connection section 25 is formed extending in an oblique direction so as to make a desired angle (θ) with respect to a normal direction (a Z-axis direction in FIG. 1) of the film-formed surface of the substrate W housed inside the film forming chamber 2. The connection section 25 allows the sputtered particle ejecting section 3 connected to an end thereof to be obliquely disposed at the desired angle with respect to the substrate W.

The second gas supply unit 22 and the exhaust control device 20 are disposed opposite each other with respect to the connection section 25. Oxygen gas supplied from the second gas supply unit 22 flows over the substrate W from a plus (+) X side to a minus (−) X side of the film forming chamber 2, i.e., to the exhaust control device 20 in a minus (−) X direction shown in FIG. 1. Argon gas supplied from the first gas supply unit 21 flows to the film forming chamber 2 through the connection section 25.

In a practical sputter apparatus, a loadlock chamber is provided outside the film forming chamber 2 in an X-axis direction. The loadlock chamber enables the substrate W to be carried in and out while the vacuum in the film forming chamber 2 is kept. The loadlock chamber is also coupled to an exhaust control device that individually controls the chamber at a vacuum atmosphere. The loadlock chamber is coupled to the film forming chamber 2 with a gate valve that air-tightly closes therebetween. As a result, the substrate W can be carried in and out while the film forming chamber 2 is not opened to the atmosphere.

The sputter apparatus 1 has a substrate holder 6 that holds a surface on which a film is formed (a film-formed surface) of the substrate W horizontally, i.e., in parallel with an X-Y plane. The substrate holder 6 is coupled to a transfer unit 6a horizontally carrying the substrate holder 6 from a side adjacent to the loadlock chamber (not shown) to another side opposite to the side. A carrying direction of the substrate W by the transfer unit 6a is in parallel with the X-axis direction in FIG. 1, and is orthogonal to lengthwise directions (a Y-axis direction) of a first target 5a and a second target 5b.

The substrate holder 6 includes a heater (heating unit) 7 for heating the substrate W held by the holder 6. In addition, the substrate holder 6 includes a third cooling unit 8c for cooling the substrate W held by the holder 6. The heater 7 is coupled to a controller 7a having a power source and the like. The heater 7 is adapted to heat the substrate holder 6 at a desired temperature by a heating up operation controlled by the controller 7a, resulting in the substrate W being heated at the desired temperature. On the other hand, the third cooling unit 8c is coupled to a third coolant circulation unit 18c with pipes and the like. The third cooling unit 8c is adapted to cool the substrate holder 6 at a desired temperature by circulating coolant supplied from the third coolant supply unit 18c, resulting in the substrate W being cooled at the desired temperature.

Sputtered Particle Ejecting Section

The sputtered particle ejecting section 3 is a facing target type sputter apparatus including two targets, the target 5a and the target 5b, disposed so as to face each other. The first target 5a is attached to a first electrode 9a having an approximately flat-plate shape while the second target 5b is attached to a second electrode 9b having an approximately flat-plate shape. The targets 5a and 5b supported by the electrodes 9a and 9b are made of a material, such as silicon, containing a constituting substance of the inorganic orientation film formed on the substrate W. As a shape of the targets 5a and 5b, an elongate plate shape extending in the Y direction in the figure is employed (refer to FIG. 2). The targets 5a and 5b are disposed so that the opposed faces are approximately parallel. The first electrode 9a is coupled to a power source 4a of a direct current power source or a high frequency power source while the second electrode 9b is coupled to a power source 4b of a direct current power source or a high frequency power source. Electric power supplied from the power sources 4a and 4b to the targets 5a and 5b generates plasma in a plasma generation region Pz between the targets 5a and 5b.

As shown in FIG. 1, the first electrode 9a is attached to a first electrode support section 28a while being insulated. On the other hand, the second electrode 9b is attached to a second electrode support section 28b while being insulated. As shown in FIGS. 1 and 2, a box-shaped chassis serving as a vacuum chamber is composed of the first and the second electrode support sections 28a and 28b and sidewall members 19, 9c and 9d. One ends (at a side in a minus (−) Xa direction) of the first and the second electrode support sections 28a and 28b are coupled to the sidewall member 19. In the Y-axis direction, one ends of the electrode support sections 28a and 28b is coupled to the side wall member 9c while the other ends is coupled to the sidewall 9d. The first electrode support section 28a, the second electrode support section 28b, and the sidewall members 9c, 9d, and 19 composing the box-shaped chassis are isolated from each other. The box-shaped chassis includes an opening 3a emitting sputtered particles at an end opposite from the sidewall member 19. Then, the box-shaped chassis is coupled to the connection section 25 projecting from the film forming chamber 2 through the opening 3a. As a result, an internal part of the box-shaped chassis is communicated with an internal part of the film forming chamber 2.

The sputtered particle ejecting section 3 is attached to the film forming chamber 2 through the connection section 25 such that face directions of the targets 5a and 5b make a desired angle θ with respect to the normal direction (the Z-axis direction in the figure) of the film-formed surface of the substrate W housed inside the film forming chamber 2. The sputtered particle ejecting section 3 has the desired angle set in a rage from 10 to 60 degrees. That is, the sputtered particle ejecting section 3 is obliquely attached with respect to the substrate W housed inside the film forming chamber 2. Accordingly, in the sputtered particle ejecting section 3, sputtered particles are emitted from the targets 5a and 5b by plasma to the film forming chamber 2 coupled through the opening 3a and the connection section 25.

A first cooling unit 8a for cooling the target 5a is disposed on one face of the first electrode 9a while the target 5a is attached on the other face opposite to the one face. The first cooling unit 8a is coupled to a first coolant circulation unit 18a with pipes and the like. Likewise, a second cooling unit 8b for cooling the target 5b is disposed on one face of the second electrode 9b while the target 5b is attached on the other face opposite to the one face. The second cooling unit 8b is coupled to a second coolant circulation unit 18b with pipes and the like. As shown in FIG. 2, the first cooling unit 8a is sized in approximately the same planar dimensions of the target 5a, and is disposed at a position overlapping with the target 5a in a plan view with the first electrode 9a interposed therebetween. Likewise, the second cooling unit 8b (not shown in FIG. 2) is disposed at a position overlapping with the target 5b in a plan view. The cooling units 8a and 8b include coolant flow passages for circulating the coolant inside thereof. The coolant supplied from the coolant circulation units 18a and 18b is circulated in the coolant flow passages to cool the targets 5a and 5b.

As shown in FIG. 2, a first magnetic field generation unit 16a is disposed so as to surround the first cooling unit 8a having a rectangular shape in a plan view. The first magnetic field generation unit 16a is composed of magnets such as permanent magnets having a rectangular shape, electromagnets, and magnets of a combination thereof. The first magnetic field generation unit 16a is disposed along an outer peripheral edge of the target 5a. Likewise, a second magnetic field generation unit 16b disposed to the second cooling unit 8b has the same shape as the first magnetic field generation unit 16a, and is disposed along an outer peripheral edge of the target 5b.

Therefore, the first magnetic field generation unit 16a and the second magnetic field generation unit 16b are disposed so as to face each other in outer peripheral areas of the targets 5a and 5b disposed so as to face each other. The magnetic field generation units 16a and 16b generate a magnetic field in the Za direction inside the sputtered particle ejecting section 3 so as to surround the targets 5a and 5b. The magnetic field traps electrons in plasma in the plasma generation region Pz. That is, the magnetic field generation units 16a and 16b function as an electron trapping unit.

Here, the cooling units 8a and 8b may be made of a conductive material, and be respectively electrically coupled to the electrodes 9a and 9b. In this case, the power sources 4a and 4b can be respectively electrically coupled to the cooling units 8a and 8b. The electrodes 9a and 9b may serve as the cooling units as well as the electrodes by forming the coolant flow passages inside thereof.

The sputtered particle ejecting section 3 according to the embodiment includes an electron capture unit 50 disposed opposite to the opening 3a of the plasma generation region Pz, i.e. a lower side (in the minus (−) Xa direction). The electron capture unit 50 is used as an anode that prevents the plasma generation region Pz from being spread by capturing electrons in the plasma generation region Pz. Further, the sputtered particle ejecting section 3 includes a sputtered particle attach section 52. The sputtered particle attach section 52 is disposed a side adjacent to the plasma generation region Pz of the electron capture unit 50, and sputtered particles 5P are attached thereto.

In the embodiment, specifically, the electron capture unit 50 includes a plurality of plate members 52a linked by a metal member 51. The metal member 51 is attached to the sidewall members 9c and 9d. The plate member 52a is made of nonmagnetic metal such aluminum, and disposed opposite to the metal member 51. The metal member 51 has a function of serving as the anode. The sputtered particles spread from the plasma generation region Pz in a direction opposing to the opening 3a (in the minus (−) Xa direction) are selectively attached to the plurality of the plate members 52a. Thus, the plurality of the plate members 52a mainly function as the sputtered particle attach section 52 that prevents the sputtered particles 5P from attaching to the metal member 51 serving as the electron capture unit.

The metal member 51 is disposed so that one side of the plate member 52a is penetrated (integrally formed), and electrically coupled to each plate member 52a. The metal member 51 is grounded and in a ground state. Further, the plate member 52 is in a ground state through the metal member 51.

That is, in the embodiment, the sputtered particles 5P are attached to the sputtered particle attach section 52. In the same manner as the metal member 51, a part of the sputtered particle attach section 52 where the sputtered particles 5P are not attached can be functioned as the electron capture unit 50. In other words, the sputtered particle attach section 52 is included in a part of the electron capture unit 50.

The plate members 52a are attached through the metal member 51 so that each face direction of the plate member 52a is parallel to the ejecting direction of the sputtered particles 5P (the Xa direction). As shown in FIG. 2, a width of the plate member 52a in the Y direction is approximately same as that of the first magnetic field generation unit 16a. Additionally, in order to improve attachment property of the sputtered particles 5P, an aluminum oxide layer is preferably formed on each surface of the plate member 52a so that a concave-convex surface is formed by plasma thermal spraying. The aluminum oxide layer includes a porous and rough surface so that particles are easily caught. As a result, the attachment property of the sputtered particles 5P of each plate member 52a is improved.

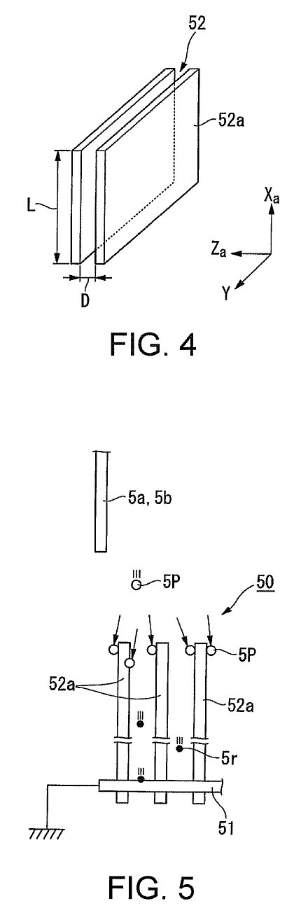

FIG. 4 is a diagram for explaining a structure of the plate member 52a. In the embodiment, as shown in FIG. 4, a length along a direction of the plasma generation region Pz in the plate member 52a, i.e., a length L in the Xa direction (a spreading direction of the sputtered particles 5P to the metal member 51) is set to be larger than a mean free path of the sputtered particles 5P flying from the plasma generation region Pz. In the sputtered particle attach section 52, a space D between each plate member 52a is set to be smaller than the mean free path of the sputtered particles 5P flying from the plasma generation region Pz.

As a result, the sputtered particle attach section 52 allows the sputtered particles 5P flying from the plasma generation region Pz to the metal member 51 to be easily collided against a surface of the plate member 52a. Further, when the sputtered particles 5P flying from the plasma generation region Pz are incident on a space between the two opposing plate members 52a from an oblique direction, the sputtered particle attach section 52 allows the sputtered particles 5P to be easily collided against the surface of one of the plate members 52a.

An inorganic orientation film is formed on the substrate W, which is a constituting member of a liquid crystal device, by the sputter apparatus 1 in the following manner. While argon gas is introduced from the first gas supply unit 21, a DC power (an RF power) is supplied to the first electrode 9a and the second electrode 9b so as to generate plasma in the plasma generation region Pz between the targets 5a and 5b. Argon ions and the like in a plasma atmosphere collide against the targets 5a and 5b so as to sputter an orientation film material (silicon) from the targets 5a and 5b as the sputtered particles 5P. Out of the sputtered particles 5P in the plasma, only the sputtered particles 5P flying from the plasma generation region to the opening 3a are ejected to the film forming chamber 2.

The sputtered particles 5P flying over the surface of the substrate W from the oblique direction react with oxygen gas flowing in the film forming chamber 2 on the substrate W to form an orientation film made of a silicon oxide.

In the embodiment, a case is described in which silicon as the sputtered particles 5P reacts with oxygen gas as the second sputter gas to form a silicon oxide on the substrate W. Alternatively, the targets 5a and 5b are made of, for example, a silicon oxide (SiOx) or an aluminum oxide (AlOy). With RF power being supplied, the targets 5a and 5b are sputtered, enabling an inorganic orientation film made of the silicon oxide or the aluminum oxide to be formed on the substrate W. In this case, the second sputter gas (oxygen gas) continuing to flow in the film forming chamber 2 can prevent an oxide composition of the formed inorganic orientation film from shifting from a desired composition. As a result, the insulation property of the inorganic orientation film can be improved.

In the sputter apparatus 1 structured as described above, the sputtered particle ejecting section 3 of a facing target type is obliquely disposed by the predetermined angle (10 to 60 degrees) with respect to the normal direction of the substrate W. As a result, an orientation angle of the sputtered particles ejected from the opening 3a of the sputtered particle ejecting section 3 can be controlled and incident on the film-formed surface.

The sputtered particle ejecting section 3 of a facing target type can achieve extremely high target use efficiency because sputtered particles not ejected from the opening 3a are mainly incident on the targets 5a and 5b to be reused. Additionally, in the sputtered particle ejecting section 3, narrowing the target distance can enhance directivity of sputtered particles ejected from the opening 3a, highly controlling an incident angle of sputtered particles that reach the substrate W. As a result, the orientation property of the columnar structure in the formed inorganic orientation film can be enhanced.

The sputter apparatus 1 of the embodiment can trap or reflect electrons 5r in the plasma generation region Pz, in forming the film, by a magnetic field generated by the magnetic field generation units 16a and 16b that surround the targets 5a and 5b of the sputtered particle ejecting section 3 and have a rectangular-frame shape, enabling plasma to be well trapped in the region between the targets 5a and 5b. As a result, increasing wettability of the substrate W due to the electrons 5r incident on the surface of the substrate W can be prevented (refer to FIG. 1).

The sputter apparatus 1 of the embodiment includes the electron trapping unit composed of the magnetic field generation units 16a and 16b. However, there may be a case that electrons may leak from the electron trapping unit. The electrons and the like leak from the electron trapping unit reach the substrate W, resulting in the wettability of the surface of the substrate W to increase. This increase may cause migration of sputtered particles to occur, hindering the formation of the columnar structure. To cope with this, in the embodiment, the electron capture unit 50 serving as an anode is additionally disposed at a lower side of the plasma generation region Pz.

The electron capture unit 50 is disposed inside the box-shaped chassis composing a chamber of the sputtered particle ejecting section 3, so that the sputtered particles 5P are attached thereto in forming the inorganic orientation film. As shown in FIG. 5, in the electron capture unit 50, the sputtered particles 5P flying from the targets 5a and 5b are attached to the plurality of the plate members 52a included in the sputtered particle attach section 52. Since each plate member 52a has the concave-convex surface, the sputtered particles 5P can be well attached.

In regard to the plate member 52a, since the length L, a length of the spreading direction (the Xa direction) of the sputtered particles 5P to the metal member 51, is set to be longer than the mean free path of the sputtered particles 5P, most of the sputtered particles 5P are attached (captured) to the surface of the plate member 52a by colliding when the particles fly to the metal member 51. Further, since the space D between each plate member 52a is shorter than the mean free path, most of the sputtered particles 5P incident on a space between the two opposing plate members 52a from the oblique direction are attached (captured) to the surface of one of the plate members 52a by colliding. Thus, the electron capture unit 50 makes the sputtered particles 5P hardly reach the metal member 51.

In the embodiment, the first gas supply unit 21 is disposed on the sidewall member 19. The first gas supply unit 21 supplies argon gas to the plasma generation region Pz. Thus, if there exists the sputtered particles 5P reaching the vicinity of the metal member 51 through the space between each plate member 52a, the argon gas supplied to the plasma generation region Pz allows the sputtered particles 5P to be blown up (to the plasma generation region Pz). Accordingly, the sputtered particles 5P are mostly attached to a side adjacent to the plasma generation region Pz of the plate member 52a. Since the electrons 5r leaked from the electron trapping unit move straight to a surface of the metal member 51, the electrons 5r reach the metal member 51 without problems even if the space between each plate member 52a is narrowed due to the attachment of the sputtered particles 5P.

Therefore, when the inorganic orientation film is formed, the electron capture unit 50 allows the function of serving as the anode to be ensured for a long period of time and the maintenance cycle to be extended by suppressing the particles 5P attaching to the surface of the metal member 51. Consequently, according to the sputter apparatus 1 of the embodiment, the inorganic orientation film having high orientation property can be formed on the substrate W for a long period of time.

The sputter apparatus 1 includes the targets 5a and 5b each having an elongate-plate shape so that sputtered particles can be ejected from the sputtered particle ejecting section 3 in a line-like form extending in the Y-axis direction. In addition, the substrate holder 6 can carry the substrate W in a direction perpendicular to the line-like shape (the X-axis direction) formed by the sputtered particles. The substrate W can be scanned by the line-like-shape formed by the sputtered particles so as to form a film in a planar shape as a continuous substrate process, resulting in high productive efficiency being achieved.

The substrate holder 6 includes the third cooling unit 8c for cooling the substrate W. The third cooling unit 8c cools the substrate W in forming a film so as to maintain the substrate W at a predetermined temperature such as a room temperature and suppress orientation material molecules deposited on the substrate W by sputtering from diffusing (migrating) on the substrate W. This results in a local growth of the orientation material being enhanced on the substrate W, enabling an orientation film grown in one axis direction in a columnar shape to be readily obtained.

The sputter apparatus 1 is not limited to the structure of the embodiment and various changes can be made without departing from the spirit of the invention. For example, in the above embodiment, the targets 5a and 5b are supported by the first electrode 9a and the second electrode 9b, both of which are two opposed sidewalls of the box-shaped chassis. However, targets may also be respectively provided to the sidewall members 9c and 9d. In such a structure, when a power source is couple to each of the sidewall members 9c and 9d so as to be functioned as an electrode to supply power to each targets, sputtered particles ejected from the targets can be used for forming a film. As a result, the film forming velocity can be increased. In addition, since the targets are disposed so as to surround the four direction of the plasma generation region, sputtered particles excluding ones ejected to the film forming chamber 2 from the opening 3a are incident on the targets surrounding the plasma generation region Pz to be reused for generating other sputtered particles. As a result, target use efficiency can be enhanced. In the structure above, cooling units of the sidewall members 9c and 9d for cooling the targets are preferably provided juxtaposed to the respective sidewall members 9c and 9d. More preferably, the arrangement of the electron trapping units (magnetic field generation units) corresponding to the targets additionally provided are changed to optimize the positional relation between the plasma generation region Pz and the targets.

Method for Manufacturing Liquid Crystal Device

A method for manufacturing a liquid crystal device (steps for forming an inorganic orientation film on the substrate W) is described that uses a device including the sputter apparatus 1 for manufacturing a liquid crystal device (hereinafter referred to as a manufacturing apparatus). First, as the substrate W, a substrate serving as a substrate for a liquid crystal device is prepared on which predetermined constitutional members such as switching elements and electrodes are formed. Next, the substrate W is housed inside the loadlock chamber juxtaposed to the film forming chamber 2, and thereafter, the inside of the loadlock chamber is depressurized so as to be a vacuum state. Independently from the step, the inside of the film forming chamber 2 is controlled at a desired vacuum level by operating the exhaust control device.

Subsequently, the substrate W is carried inside the film forming chamber 2 to be set to the substrate holder 6. Then, the substrate W is heated by the heater 7 of the substrate holder 6, for example, at about 250° C. to about 300° C. to remove moisture and gas adsorbed on the surface of the substrate W as a pretreatment for forming an orientation film. After the heating by the heater 7 is stopped, in order to suppress increasing the substrate temperature due to sputtering, coolant is circulated in the cooling unit 8c by operating the coolant circulation unit 18c so as to maintain the substrate W at a predetermined temperature such as a room temperature.

Next, argon gas is introduced inside the sputtered particle ejecting section 3 from the first gas supply unit 21 at a predetermined flow rate while oxygen gas is introduced inside the film forming chamber 2 from the second gas supply unit 22 at a predetermined flow rate. Meantime, the inside of the film forming chamber 2 is controlled at a predetermined operational pressure, for example, about 10⁻¹ Pa by operating the exhaust control device 20. In the manufacturing apparatus of the embodiment, only argon gas is introduced in the plasma generation region, i.e., in front of the targets 5a and 5b while oxygen gas is flowed over the substrate W from the gas supply path of different supply system because oxygen radicals and negative oxygen ions are generated in the oxygen gas plasma. In forming a film, the substrate W is preferably maintained at a room temperature by operating the heater 7 and the cooling unit 8c as needed.

Under such film forming conditions, sputtering is conducted in the sputtered particle ejecting section 3 while the substrate W is moved by the transfer unit 6a in the X direction in FIG. 1 at a predetermined velocity. In the sputtered particle ejecting section 3 of a facing target type, sputtered particles (silicon) serving as an orientation film material are ejected from the targets 5a and 5b. The sputtered particles 5P moving in the direction between the targets are trapped in the plasma generation region Pz while only the sputtered particles 5P moving in the target face direction are ejected from the opening 3a into the film forming chamber 2 to be incident on the substrate W.

The sputtered particles 5P are selectively incident on only the film-formed surface of the substrate W so as to form a film of a silicon oxide after reacting with oxygen gas on the substrate W. As described above, the sputtered particles 5P ejected from the sputtered particle ejecting section 3 obliquely disposed with respect to the substrate W are incident on the film-formed surface of the substrate W at the predetermined angle θ, i.e., from 10 to 60 degrees. As a result, an inorganic orientation film deposited on the substrate W after reacting oxygen gas and the sputtered particles 5P has a columnar structure inclined at an angle corresponding to the incident angle.

The inorganic orientation film formed on the substrate W by the manufacturing apparatus has the columnar structure having the desired angle. A liquid crystal device including the orientation film can well control the pretilt angle of liquid crystal by the inorganic orientation film.

At this time, since the electron trapping unit (the magnetic field generation units 16a and 16b) disposed at the opening 3a of the sputtered particle ejecting section 3 and the electron capture unit 50 trap or reflect the electrons and the ionized substance in the plasma generation region Pz, the electrons and the ionized substance can be prevented from reaching the substrate W. As described above, the metal member 51 can be prevented from being insulated due to the attachment of the sputtered particles 5P, the electron capture unit 50 can fulfill the function of serving as the anode for a long period of time, and the inorganic orientation film having good quality can be manufactured with a high film deposition rate.

Thereafter, the substrate W on which the inorganic orientation film has been formed is bonded to another substrate manufactured in a different steps. Liquid crystal is sealed between the substrates so that a liquid crystal device is completed. In the method for manufacturing a liquid crystal according to the invention, manufacturing steps excluding the step for forming the inorganic orientation film can employ the known manufacturing methods. The manufacturing apparatus of the invention can efficiently manufacture an inorganic orientation film superior in orientation property with a desired columnar structure since the device is capable of extending the maintenance cycle of the sputtering apparatus 1.

What is claimed is:

1. A sputtering apparatus, comprising:
a film forming chamber housing a substrate; and
a sputtered particle ejecting section ejecting a sputtered particle from a pair of targets facing each other with a plasma generation region between the targets, wherein the sputtered particle ejecting section includes an electron capture unit that is disposed opposite to the film forming chamber and captures an electron in the plasma generation region, and a sputtered particle attach section that is disposed adjacent to the film forming chamber and attaches the particle.

2. The sputtering apparatus according to claim 1, wherein the sputtered particle attach section is included in a part of the electron capture unit.

3. The sputtering apparatus according to claim 1, wherein the sputtered particle attach section includes a plurality of plate members, wherein the plate members are disposed so that each face direction of the plate members coincides with an ejecting direction of the sputtered particle and each face of the plate members is parallel to each other.

4. The sputtering apparatus according to claim 3, wherein a length of the plate member in a direction toward the plasma generation region is larger than a mean free path of the sputtered particle.

5. The sputtering apparatus according to claim 3, wherein a space between the plurality of the plate members is smaller than a mean free path of the sputtered particle.

6. The sputtering apparatus according to claim 1, wherein the sputtered particle ejecting section includes a sputter gas supply unit that supplies a sputter gas to the plasma generation region, and is disposed opposite to the plasma generation region of the electron capture unit.

7. A manufacturing apparatus for a liquid crystal device, comprising:
a liquid crystal layer sandwiched between a pair of substrates facing each other;
an inorganic orientation film formed at an inner side of at least one of the substrates; and
the sputtering apparatus according to claim 1, wherein the inorganic orientation film is formed by the sputtering apparatus.
